(19) United States
(12) Patent Application Publication
(10) Pub. No.: US 2023/0395637 A1
(43) Pub. Date: Dec. 7, 2023

(54) PHOTOELECTRIC CONVERSION APPARATUS AND PHOTOELECTRIC CONVERSION SYSTEM

(71) Applicant: CANON KABUSHIKI KAISHA, Tokyo (JP)

(72) Inventor: HIROSHI SEKINE, Kanagawa (JP)

(21) Appl. No.: 18/326,774

(22) Filed: May 31, 2023

(30) Foreign Application Priority Data
Jun. 6, 2022 (JP) 2022-091510

(51) Int. Cl. H01L 27/146

(52) U.S. Cl. CPC H01L 27/14636; H01L 27/14645

(57) ABSTRACT

An apparatus includes a photodiode in a first substrate having a first surface and a second surface opposite the first surface. The photodiode includes a first region of a first conductivity type at a first depth, a second region of a second conductivity type at a second depth deeper than the first depth with respect to the second surface, a third region at a third depth deeper than the second depth with respect to the second surface, a fourth region in contact with the third region, a first conductive line connected to the first region and disposed adjacent to the second surface to read a signal from the first region, and a second conductive line provided adjacent to the first surface. The difference between potentials applied to the first and second conductive lines is the breakdown voltage or greater.

### BACKGROUND

### Technical Field

The aspect of the embodiment relates to a photoelectric conversion apparatus and a photoelectric conversion system using the photoelectric conversion apparatus.

### Description of the Related Art

International Publication No. 2017/169882 describes a photoelectric conversion apparatus provided with a through electrode for supplying voltage to a semiconductor substrate having a photoelectric conversion element formed therein.

Japanese Patent Laid-Open No. 2018-0201005 describes a photoelectric conversion apparatus provided with an electrode for supplying voltage to a semiconductor substrate having an avalanche photodiode formed therein.

According to the structure described in International Publication No. 2017/169882, the degree of freedom of arrangement of transistors is limited due to the presence of a through electrode. In addition, according to the structure described in Japanese Patent Laid-Open No. 2018-0201005, the degree of design freedom of the configurations of a portion in which an anode voltage is supplied to a substrate to maintain the DCR (Dark Count Rate) and a portion in which a cathode voltage is supplied to the substrate are limited.

### SUMMARY

According to an aspect of the embodiments, an apparatus includes a photodiode disposed in a first substrate having a first surface and a second surface opposite the first surface. The photodiode includes a first region of a first conductivity type disposed at a first depth, a second region of a second conductivity type disposed at a second depth that is deeper than the first depth with respect to the second surface, a third region disposed at a third depth that is deeper than the second depth with respect to the second surface, a fourth region in contact with the third region, a first conductive line connected to the first region and disposed adjacent to the second surface, where the first conductive line is used to read a signal from the first region, and a second conductive line disposed adjacent to the first surface. The difference between a potential applied to the first conductive line and a potential applied to the second conductive line is greater than or equal to a breakdown voltage.

According to another aspect of the embodiments, an apparatus includes a first substrate having a first surface on which light is incident and the second surface opposite the first surface and a second substrate stacked adjacent to the second surface of the first substrate. The first substrate includes an element including a first region of a first conductivity type and a second region of a second conductivity type, a third region in contact with the second region, a first conductive line connected to the first region and used to read out a signal from the first region, and a second conductive line provided adjacent to the first surface and used to supply a potential to the first substrate. The first substrate includes a third surface facing the second surface, a fourth surface opposite the third surface, and a transistor formed on the fourth surface. The transistor is a part of a pixel circuit that processes a signal output from the element.

Further features of the disclosure will become apparent from the following description of exemplary embodiments with reference to the attached drawings.

### BRIEF DESCRIPTION OF THE DRAWINGS

FIG. 1 is a schematic illustration of a photoelectric conversion apparatus according to an embodiment.

FIG. 2 is a schematic illustration of a sensor substrate of the photoelectric conversion apparatus according to the embodiment.

FIG. 3 is a schematic illustration of a circuit substrate of the photoelectric conversion apparatus according to the embodiment.

FIG. 4 illustrates a configuration example of a pixel circuit of the photoelectric conversion apparatus according to the embodiment.

FIGS. 5A to 5C are schematic illustrations of driving of the pixel circuit of the photoelectric conversion apparatus according to the embodiment.

FIG. 6 illustrates a configuration example of the pixel circuit of the photoelectric conversion element according to the embodiment.

FIG. 7 is a plan view of a chip end portion of a photoelectric conversion apparatus according to a first embodiment.

FIG. 8 is a cross-sectional view of the photoelectric conversion apparatus according to the first embodiment.

FIGS. 9A and 9B are plan views of the photoelectric conversion apparatus according to the first embodiment.

FIGS. 10A and 10B are plan views of the photoelectric conversion apparatus according to the first embodiment.

FIG. 11 is a cross-sectional view of the photoelectric conversion apparatus according to the first embodiment.

FIG. 12 is a cross-sectional view of the photoelectric conversion apparatus according to the first embodiment.

FIG. 13 is a cross-sectional view of a photoelectric conversion apparatus according to a second embodiment.

FIG. 14 is a cross-sectional view of the photoelectric conversion apparatus according to the second embodiment.

FIG. 15 is a cross-sectional view of a photoelectric conversion apparatus according to a third embodiment.

FIG. 16 is a cross-sectional view of the photoelectric conversion apparatus according to the third embodiment.

FIG. 17 is a cross-sectional view of the photoelectric conversion apparatus according to the third embodiment.

FIG. 18 is a cross-sectional view of a photoelectric conversion apparatus according to a fourth embodiment.

FIGS. 19A to 19C are plan views of the photoelectric conversion apparatus according to the fourth embodiment.

FIG. 20 is a cross-sectional view of the photoelectric conversion apparatus according to the fourth embodiment.

FIG. 21 is a cross-sectional view of the photoelectric conversion apparatus according to the fourth embodiment.

FIG. 22 is a cross-sectional view of the photoelectric conversion apparatus according to the fourth embodiment.

FIG. 23 is a cross-sectional view of a photoelectric conversion apparatus according to a fifth embodiment.

FIG. 24 is a cross-sectional view of a photoelectric conversion apparatus according to a sixth embodiment.

FIG. 25 is a functional block diagram of a photoelectric conversion system according to a seventh embodiment.

FIG. 26A is a functional block diagram of a photoelectric conversion system according to an eighth embodiment; and FIG. 26B illustrates a photoelectric conversion system that captures a front view image.

FIG. 27 is a functional block diagram of a photoelectric conversion system according to a ninth embodiment.

FIG. 28 is a functional block diagram of a photoelectric conversion system according to a tenth embodiment.

FIGS. 29A and 29B illustrate photoelectric conversion systems (i.e., smart glasses) according to an eleventh embodiment.

### DESCRIPTION OF THE EMBODIMENTS

Embodiments described below are for embodying the technical concept of the disclosure and are not intended to limit the disclosure. The sizes and positional relationships of members illustrated in the drawings may be exaggerated for clarity of description. In the following description, the same configuration may be identified by the same reference numeral, and description may be omitted.

The embodiments of the disclosure are described in detail below with reference to the accompanying drawings. In the following description, the terms indicating specific directions and positions (for example, “upper”, “lower”, “right”, “left”, and other terms including these terms) are used as necessary. These terms are used to facilitate understanding of the embodiments with reference to the drawings, and the technical scope of the disclosure is not limited by the meanings of the terms.

As used herein, the term “plan view” is used to refer to a view in a direction perpendicular to the light incident surface of a semiconductor layer. The term “cross-sectional view” refers to a plane in a direction perpendicular to the light incident surface of the semiconductor layer. When the light incident surface of the semiconductor layer is microscopically rough, the plan view is defined on the basis of the light incident surface of the semiconductor layer when viewed macroscopically.

In the following description, the anode of an avalanche photodiode (APD) is set at a fixed electric potential, and a signal is taken from the cathode side. Therefore, a semiconductor region of a first conductivity type in which the charges of a polarity the same as that of a signal charge are majority carriers is an N-type semiconductor region, and a semiconductor region of a second conductivity type in which the charges of the polarity different from that of a signal charge are majority carriers is a P-type semiconductor region.

The disclosure can also be applied when the cathode of the APD is set at a fixed electric potential and the signal is taken from the anode side. In this case, the semiconductor region of the first conductivity type in which charges of a polarity the same as that of the signal charge are majority carriers is a P-type semiconductor region, and the semiconductor region of the second conductivity type in which charges of a polarity different from that of the signal charge are majority carriers is an N-type semiconductor region. Hereinafter, the case where one of the nodes of the APD is set to a fixed electric potential is described below. However, the potentials of both nodes may vary.

The term “impurity concentration” as simply used herein refers to the net impurity concentration obtained after subtracting the amount compensated by the impurity of an opposite conductivity type. That is, the term “impurity concentration” refers to the NET doping concentration. A region in which the P-type additive impurity concentration is higher than the N-type additive impurity concentration is a P-type semiconductor region. In contrast, a region in which the N-type additive impurity concentration is higher than the P-type additive impurity concentration is an N-type semiconductor region.

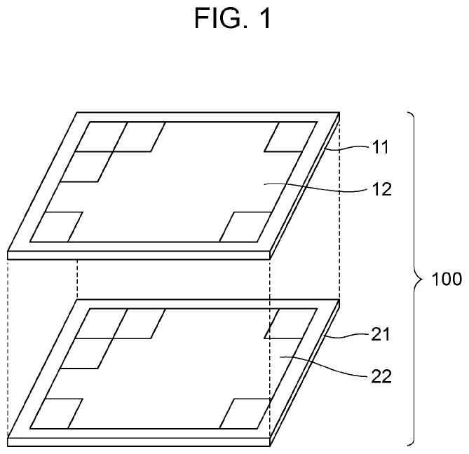

A configuration common to all embodiments of a photoelectric conversion apparatus and a method for driving the photoelectric conversion apparatus according to the disclosure are described below with reference to FIGS. 1 to 4 and FIGS. 5A to 5C.

FIG. 1 illustrates the configuration of a lamination type photoelectric conversion apparatus 100 according to an embodiment of the disclosure.

The photoelectric conversion apparatus 100 is configured by stacking and electrically connecting a sensor substrate 11 with a circuit substrate 21. The sensor substrate 11 has a first semiconductor layer including photoelectric conversion elements 102 (described below) and a first wiring structure. The circuit substrate 21 has a second semiconductor layer including circuits, such as a signal processing unit 103 (described below), and a second wiring structure. The photoelectric conversion apparatus 100 is configured by stacking the second semiconductor layer, the second wiring structure, the first wiring structure, and the first semiconductor layer in this order. The photoelectric conversion apparatus described in each of the embodiments is a back-illuminated photoelectric conversion apparatus in which light is incident on a first surface and a circuit substrate is disposed on a second surface.

Although the sensor substrate 11 and the circuit substrate 21 in the form of diced chips are described below, the forms are not limited to chips. For example, the substrates may be wafers. In addition, the substrates in the form of wafers may be stacked and then diced or may be made into chips and then stacked and bonded.

The sensor substrate 11 has a pixel region 12 disposed therein, and the circuit substrate 21 has, disposed therein, a circuit region 22 for processing signals detected by the pixel region 12.

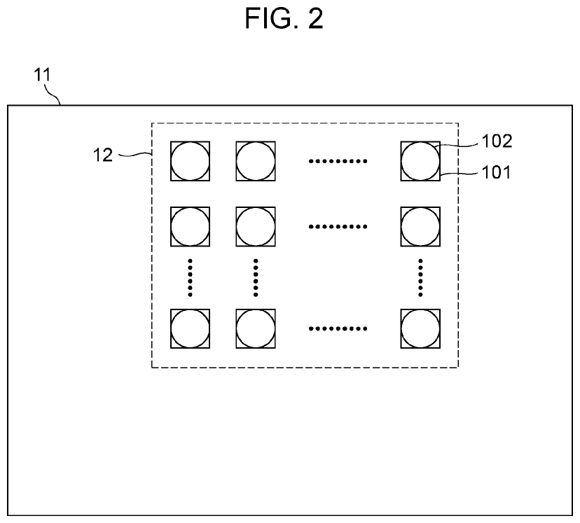

FIG. 2 illustrates an arrangement example in the sensor substrate 11. Pixels 101 each having a photoelectric conversion element 102 including an avalanche photodiode (APD) are arranged in a two-dimensional array in plan view to form the pixel region 12.

The pixels 101 are typically pixels for forming an image. However, when used for TOF (Time of Flight), the pixels 101 do not necessarily form an image. That is, the pixels 101 may be pixels for measuring the time and the amount of light when the light reaches the pixels 101.

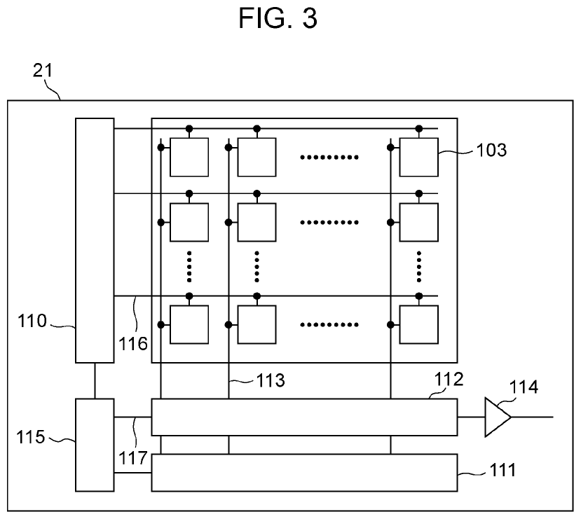

FIG. 3 is a configuration diagram of the circuit substrate 21. The circuit substrate 21 includes the signal processing units 103 that process charges photoelectrically converted by the photoelectric conversion elements 102 illustrated in FIG. 2, a column circuit 112, a control pulse generation circuit 115, a horizontal scanning circuit unit 111, a signal lines 113, and a vertical scanning circuit unit 110.

The photoelectric conversion element 102 illustrated in FIG. 2 and the signal processing unit 103 illustrated in FIG. 3 are electrically connected via a connection conductive line provided for each of the pixels.

The vertical scanning circuit unit 110 receives a control pulse supplied from the control pulse generation unit 115 and supplies the control pulse to each of the pixels. Logic circuits, such as a shift register and an address decoder, are used in the vertical scanning circuit unit 110.

A signal output from the photoelectric conversion element 102 of the pixel is processed by the signal processing unit 103. The signal processing unit 103 includes a counter, a memory, and the like, and a digital value is held in the memory.

The horizontal scanning circuit unit 111 inputs a control pulse for sequentially selecting each of columns to the signal processing unit 103 to read a signal from the memory of each of the pixels that holds the digital signal.

The signal is output to the signal line 113 from the signal processing unit 103 of the pixel selected by the vertical scanning circuit unit 110 for the selected column.

The signal output to the signal line 113 is output to an external recording unit or the signal processing unit of the photoelectric conversion apparatus 100 via an output circuit 114.

In FIG. 2, the array of photoelectric conversion elements in the pixel region may be a one-dimensional array. In addition, the effect of the disclosure can be obtained even if there is one pixel, and the disclosure also includes the case where there is one pixel. The function of the signal processing unit does not necessarily have to be provided for each of the photoelectric conversion elements. For example, one signal processing unit may be shared by a plurality of photoelectric conversion elements, and signal processing may be performed sequentially.

As illustrated in FIGS. 2 and 3, a plurality of signal processing units 103 are arranged in a region that overlaps the pixel region 12 in plan view. The vertical scanning circuit unit 110, the horizontal scanning circuit unit 111, the column circuit 112, the output circuit 114, and the control pulse generation unit 115 are arranged so as to overlap a region between the edges of the sensor substrate 11 and the edge of the pixel region 12 in plan view. That is, the sensor substrate 11 has the pixel region 12 and a non-pixel region disposed surrounding the pixel region 12, and the vertical scanning circuit unit 110, the horizontal scanning circuit unit 111, the column circuit 112, the output circuit 114, and the control pulse generation unit 115 are arranged in the region that overlaps the non-pixel region in plan view.

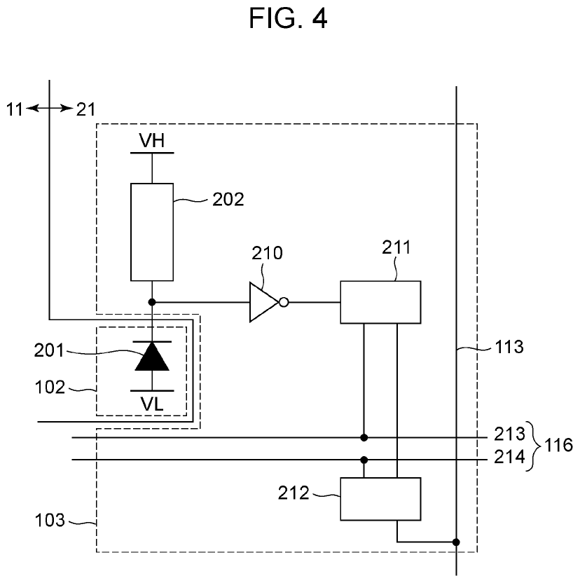

FIG. 4 is an example of a block diagram including the equivalent circuit of the configuration illustrated in FIGS. 2 and 3.

In FIG. 2, the photoelectric conversion element 102 including an APD 201 is provided in the sensor substrate 11, and the other members are provided in the circuit substrate 21.

The APD 201 generates charge pairs in accordance with incident light by photoelectric conversion. A voltage VL (a first voltage) is supplied to the anode of the APD 201. In addition, a voltage VH (a second voltage) that is higher than the voltage VL supplied to the anode is supplied to the cathode of the APD 201. A reverse bias voltage (a voltage equal to or higher than the breakdown voltage) is supplied to the anode and cathode so that the APD 201 performs an avalanche multiplication operation. By supplying such voltages, charges generated by the incident light undergo avalanche multiplication, which generates an avalanche current.

When a reverse bias voltage is supplied, an APD has two modes of operation: the Geiger mode in which the potential difference between the anode and cathode is greater than the breakdown voltage and the linear mode in which the potential difference between the anode and cathode is less than or equal to the breakdown voltage.

An APD operated in the Geiger mode is referred to as an SPAD. For example, the voltage VL (the first voltage) is −30 V, and the voltage VH (the second voltage) is 1 V. The APD 201 may be operated in either the linear mode or the Geiger mode.

A quenching element 202 is connected to a power source that supplies the voltage VH and the APD 201. The quenching element 202 functions as a load circuit (a quenching circuit) during signal multiplication by avalanche multiplication, reduces the voltage supplied to the APD 201, and has a function of reducing avalanche multiplication (a quenching operation). In addition, the quenching element 202 has a function of causing a current corresponding to the voltage drop due to the quenching operation to flow and returning the voltage supplied to the APD 201 to the voltage VH (a recharge operation).

The signal processing unit 103 includes a waveform shaping unit 210, a counter circuit 211, and a selection circuit 212. Herein, the signal processing unit 103 can include one of the waveform shaping unit 210, the counter circuit 211, and the selection circuit 212. The signal processing unit 103 is also referred to as a “pixel circuit” that processes a signal output from the photoelectric conversion element.

The waveform shaping unit 210 shapes a change in the potential of the cathode of the APD 201 obtained during photon detection and outputs a pulse signal. For example, an inverter circuit is used as the waveform shaping unit 210. Although FIG. 4 illustrates an example in which one inverter is used as the waveform shaping unit 210, a circuit in which a plurality of inverters are connected in series may be used, or another circuit having a waveform shaping effect may be used.

The counter circuit 211 counts the pulse signals output from the waveform shaping unit 210 and holds a count value. Furthermore, when a control pulse pRES is supplied via a drive line 213, a count value held in the counter circuit 211 is reset.

The selection circuit 212 is supplied with a control pulse pSEL from the vertical scanning circuit unit 110 illustrated in FIG. 3 via a drive line 214 illustrated in FIG. 4 (not illustrated in FIG. 3) and switches between connection and disconnection of the counter circuit 211 from the signal line 113. The selection circuit 212 includes, for example, a buffer circuit for outputting a signal.

A switch, such as a transistor, may be provided between the quenching element 202 and the APD 201 or between the photoelectric conversion element 102 and the signal processing unit 103 to switch the electrical connection. Similarly, the voltage VH and the voltage VL supplied to the photoelectric conversion element 102 may be electrically switched using a switch, such as a transistor.

According to the present embodiment, the configuration using the counter circuit 211 is described. However, the photoelectric conversion apparatus 100 that acquires the pulse detection timing may be achieved by using a time-to-digital converter (hereinafter referred to as a TDC) and a memory instead of the counter circuit 211. At this time, the generation timing of the pulse signal output from the waveform shaping unit 210 is converted into a digital signal by the TDC. To measure the timing of the pulse signal, the TDC receives a control pulse pREF (a reference signal) supplied thereto from the vertical scanning circuit unit 110 illustrated in FIG. 1 via the drive line. The TDC acquires a signal in the form of a digital signal when the input timing of the signal output from each of the pixels via the waveform shaping unit 210 is regarded as a time relative to the control pulse pREF.

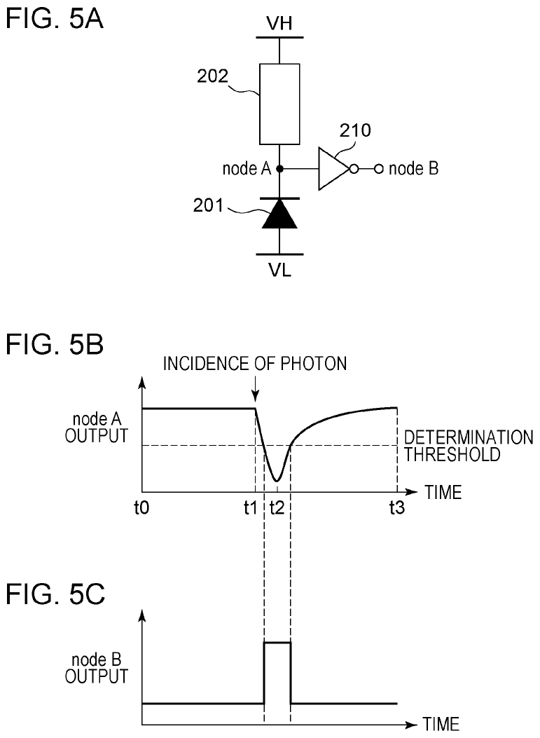

FIGS. 5A to 5C are schematic illustrations of the relationship between the operation performed by the APD and the output signals.

FIG. 5A illustrates the APD 201, the quenching element 202, and the waveform shaping unit 210 illustrated in FIG. 4. In FIG. 5A, let node A be the input side of the waveform shaping unit 210, and let node B be the output side of the waveform shaping unit 210. Then, FIG. 5B illustrates a change in the waveform in the node A illustrated in FIG. 5A, and FIG. 5C illustrates a change in the waveform in the node B illustrated in FIG. 5A.

Between time t0 and time t1, a potential difference of (VH−VL) is applied to the APD 201 illustrated in FIG. 5A. When a photon is incident on the APD 201 at time t1, avalanche multiplication occurs in the APD 201, an avalanche multiplication current flows through the quenching element 202, and the voltage in the node A drops. When the voltage drop amount further increases and the potential difference applied to the APD 201 decreases, the avalanche multiplication in the APD 201 stops at time t2, and the voltage level of the node A does not drop beyond a certain value. Thereafter, between time t2 to time t3, a current that compensates for the voltage drop from the voltage VL flows through the node A. After time t3, the node A remains at the original potential level. At this time, a portion of the output waveform in the node A exceeding a certain threshold is waveform-shaped by the waveform shaping unit 210 and is output as a signal in the node B.

It should be noted that the arrangement of the signal lines 113 and the arrangement of the column circuit 112 and the output circuit 114 are not limited to those illustrated in FIG. 3. For example, the signal lines 113 may be arranged extending in the row direction, and the column circuit 112 may be disposed at the end of the signal line 113 in the extending direction.

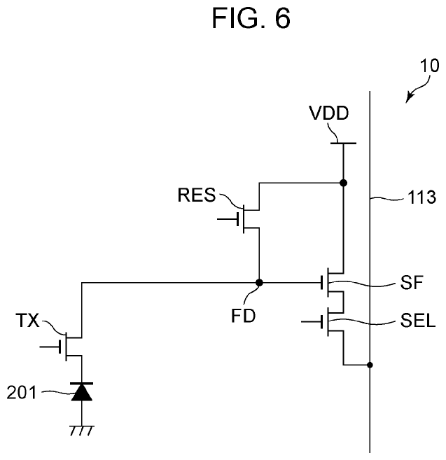

While the description above has been made with reference to a photoelectric conversion element that is a pixel including an APD, the photoelectric conversion element may be a CMOS image sensor. FIG. 6 illustrates an example of the equivalent circuit of a pixel of the photoelectric conversion apparatus according to the present embodiment.

In FIG. 6, the photoelectric conversion element 102 including the APD 201 and the transfer transistor TX are provided in the sensor substrate 11, and the other members are provided in the circuit substrate 21. The arrangement illustrated in FIG. 6 is merely an example, and the members provided in the sensor substrate 11 and the members provided in the circuit substrate 21 are appropriately selected.

The signal processing unit 103 includes a transfer transistor TX, a floating diffusion FD, a reset transistor RES, a source follower transistor SF, and a selection transistor SEL. A control signal for controlling each of the transistors is input from the vertical scanning circuit unit 110 illustrated in FIG. 3 to the gate of the transistor via a control line.

Furthermore, while the disclosure has been described with reference to the photoelectric conversion apparatus in which a plurality of semiconductor substrates are stacked, the photoelectric conversion apparatus may be a photoelectric conversion apparatus in which pixels and circuits are formed on the same semiconductor substrate.

A photoelectric conversion apparatus according to each of the embodiments is described below.

### First Embodiment

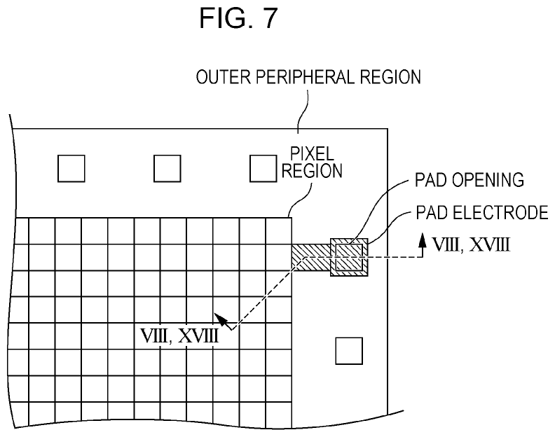

A photoelectric conversion apparatus according to the first embodiment is described below with reference to FIGS. 7 to 12. In the photoelectric conversion apparatus according to the first embodiment, pixels including CMOS image sensors and circuits are formed in the same semiconductor substrate.

FIG. 7 is a plan view of an end portion of a chip. One of the corners of a rectangular chip is illustrated. The chip has a pixel region in which pixels are arranged in an array and an outer peripheral region disposed around the pixel region, and the outer peripheral region has a Pad electrode provided for input and output of signals to and from the outside and a pad opening formed in the substrate to expose the Pad electrode to the outside.

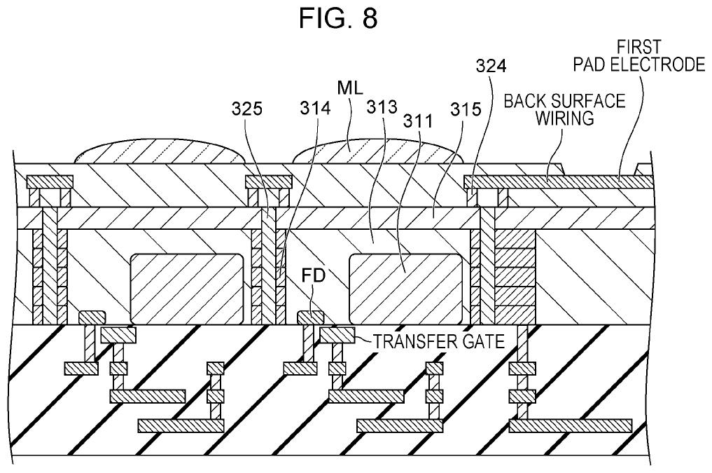

FIG. 8 is a cross-sectional view of two pixels of the photoelectric conversion elements 102 of the photoelectric conversion apparatus according to the first embodiment, taken in a direction perpendicular to the surface direction of the substrate. FIG. 8 corresponds to a cross-sectional view taken along line VIII-VIII of FIG. 7.

The structure and function of the photoelectric conversion element 102 are described below. The photoelectric conversion element 102 includes an N-type first semiconductor region 311 and an N-type third semiconductor region 313. The photoelectric conversion elements 102 further includes a P-type fourth semiconductor region 314 and a P-type fifth semiconductor region 315.

According to the present embodiment, in the cross section illustrated in FIG. 8, the N-type first semiconductor region 311 is formed in the vicinity of a second surface opposite a first surface that is the light incident surface, and the N-type third semiconductor region 313 is formed around the first semiconductor region 311. A voltage is supplied from a contact electrode 324 provided in a wiring structure adjacent to the light incident surface of the substrate to the P-type fifth semiconductor region 315 that overlaps the third semiconductor region 313 in plan view.

Pixels are separated by a pixel separation portion 325 having a trench structure, and the P-type fourth semiconductor region 314 formed around the pixel separation portion 325 separates adjacent photoelectric conversion elements from each other by a potential barrier. Since the photoelectric conversion elements are also separated by the potential of the fourth semiconductor region 314, the trench structure, such as the pixel separation portion 325, is not essential for the pixel separation portion. Thus, when the pixel separation portion 325 having a trench structure is provided, the depth and position are not limited to those in the configuration illustrated in FIG. 6. The pixel separation portion 325 may be DTI (deep trench isolation) that penetrates the semiconductor layer or may be DTI that does not penetrate the semiconductor layer. A metal may be embedded in the DTI to improve the light shielding performance. The pixel separation portion 325 may be made of SiO, a fixed charge film, a metal member, Poly-Si, or any combination thereof. A configuration may be employed in which the pixel separation portions 325 surround the entire periphery of the photoelectric conversion element in plan view. Alternatively, a configuration may be employed in which, for example, the pixel separation portions 325 are disposed on the opposite sides of the photoelectric conversion element.

A pinning film and a planarization film (neither is illustrated) are formed adjacent to the light incident surface of the semiconductor layer. Furthermore, microlenses ML are formed adjacent to the light incident surface. Still furthermore, a filter layer (not illustrated) or the like may be disposed adjacent to the light incident surface. As the filter layer, an optical filter, such as a color filter, an infrared cut filter, or a monochrome filter, can be used. As the color filter, an RGB color filter, an RGBW color filter, or the like can be used.

The wiring structure including a conductor and an insulating film is provided on the surface opposite the light incident surface of the semiconductor layer. An interlayer film, which is an insulating film, is provided between a conductive line and the semiconductor layer and between wiring layers.

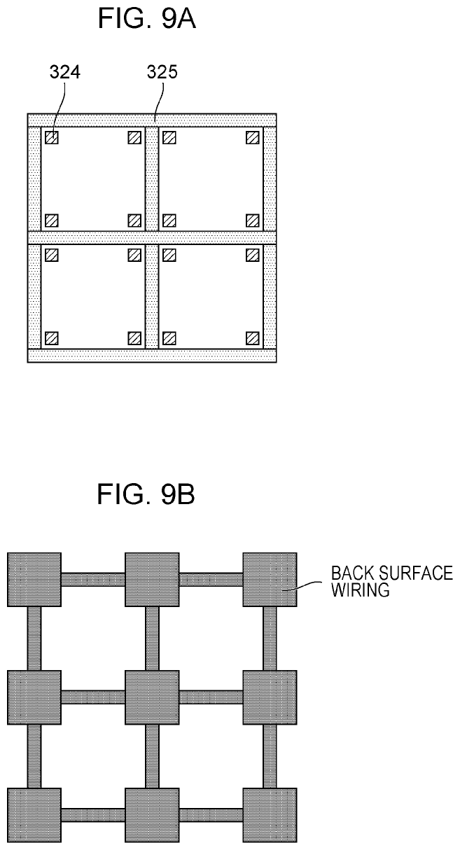

FIGS. 9A and 9B are plan views of four pixels of the photoelectric conversion apparatus according to the first embodiment. FIGS. 9A and 9B are plan views as viewed from the light incident surface side. FIG. 9A illustrates the layout of the contact electrodes 324 and the pixel separation portions 325, and FIG. 9B illustrates the wiring layout corresponding to FIG. 9A.

According to the layout illustrated in FIG. 9A, each of the pixels is surrounded by the pixel separation portions 325. The contact electrodes 324 are disposed at the four corners of each of the pixels. If at least one contact electrode 324 is disposed for each of the pixels, a voltage can be provided to the fifth semiconductor region 315. However, by placing the contact electrodes 324 at the four corners of the pixel, the voltage can be applied to various portions of the pixel in a symmetrical fashion.

In addition, as illustrated in FIG. 9B, the conductive lines connected to the contact electrodes 324 that supply a voltage to the pixels are connected in a mesh-like manner and are arranged so as to cover the pixel separation portions 325.

In one embodiment, the contact electrode 324 and the semiconductor substrate is joined by low resistance ohmic contact. For this purpose, for example, the contact electrode 324 may be formed by implanting ions into the contact region from the light incident surface side and activating the contact region by laser annealing.

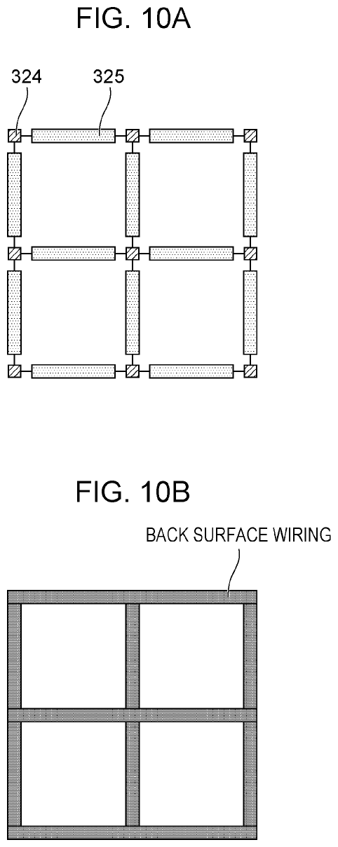

FIGS. 10A and 10B are modified plan views of the four pixels of the photoelectric conversion apparatus according to the first embodiment. FIG. 10A illustrates the layout of the contact electrodes 324 and the pixel separation portions 325, and FIG. 10B illustrates the wiring layout corresponding to FIG. 10A. In the plan views illustrated in FIGS. 9A and 9B, the pixel separation portions 325 surround each of the pixels. However, a configuration may be employed in which the pixel separation portion 325 is not formed at the corners of a pixel and instead a gap is formed between the pixel separation portions 325.

By employing such a structure, the width of the conductive line that covers the pixel separation portion 325 can be reduced than in the structure in which the pixel separation portions 325 surround the entire periphery of a pixel. Thus, incident light blocked by the conductive line can be reduced. Light loss due to a conductive line can be reduced particularly when pixels are tiny.

When a gap is provided between the pixel separation portions 325, a voltage can be supplied to the pixel by supplying a voltage to the fifth semiconductor region 315 in the outer peripheral region without forming the contact electrode 324 in the pixel region. However, a voltage drop occurs between the edge portion of the pixel region near the outer peripheral region and the central portion of the pixel region distant from the outer peripheral region, which may cause a difference between the voltages applied to the pixels.

Therefore, by providing the contact electrode 324 in the pixel region, a constant voltage can be provided to the pixels throughout the pixel region. Note that the density of the contact electrodes 324 may be reduced as compared with the density of the pixels. For example, one contact electrode 324 may be provided for a plurality of pixels (for example, four pixels).

In the cross-sectional view illustrated in FIG. 8, the Pad electrode is provided in the wiring structure adjacent to the light incident surface of the substrate. However, the location of the Pad electrode is not limited thereto.

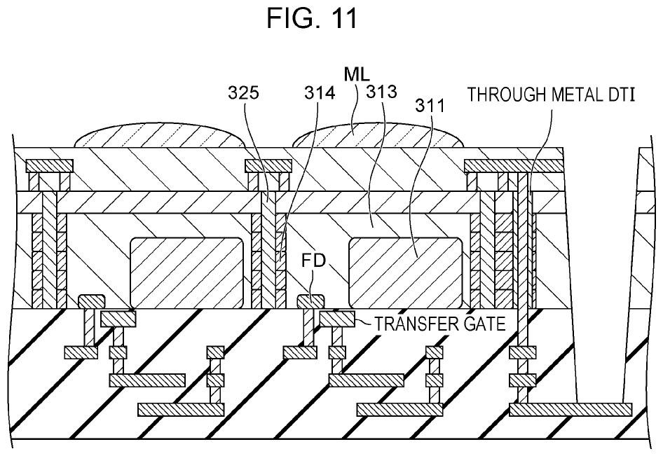

FIG. 11 is a cross-sectional view of the photoelectric conversion apparatus according to the first embodiment. In the photoelectric conversion apparatus illustrated in FIG. 11, a Pad electrode is located in a wiring structure provided adjacent to the surface opposite the light incident surface. A voltage input from the Pad electrode is provided in the outer peripheral region and is connected to a conductive line located adjacent to the light incident surface via a through electrode that penetrates the semiconductor substrate. To supply a voltage, a through metal DTI (metal is embedded in the pixel separation portion 325 that penetrates the semiconductor layer) illustrated in FIG. 8 or a through silicon via (TSV) may be used, for example.

According to the configuration, the process of forming a pad opening in the substrate can be reduced, as compared with the configuration illustrated in FIG. 8. According to the configuration illustrated in FIG. 8, a Pad opening process for the Pad electrodes provided in the wiring structure adjacent to the surface opposite the light incident surface and a pad opening process for the Pad electrode provided in the wiring structure adjacent to the light incident surface are needed. In contrast, to achieve the present configuration, only one pad opening process is required for the Pad electrode provided in the wiring structure adjacent to the surface opposite the light incident surface.

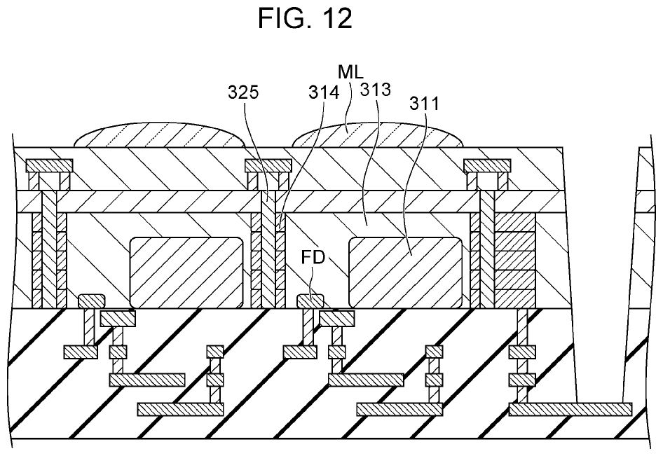

FIG. 12 illustrates a further modified example of the structure illustrated in FIG. 11. FIG. 12 is a cross-sectional view of two pixels of the photoelectric conversion apparatus according to the first embodiment.

In the configuration illustrated in FIG. 12, Pad electrodes are provided in the wiring structure adjacent to the surface opposite the light incident surface of the substrate facing, as in FIG. 11. Unlike the configuration illustrated in FIG. 11, a voltage is supplied to the conductive line adjacent to the light incident surface via the P-type semiconductor region. According to the configuration, unlike the configuration illustrated in FIG. 11, it is not necessary to form a through electrode that penetrates the semiconductor substrate.

### Second Embodiment

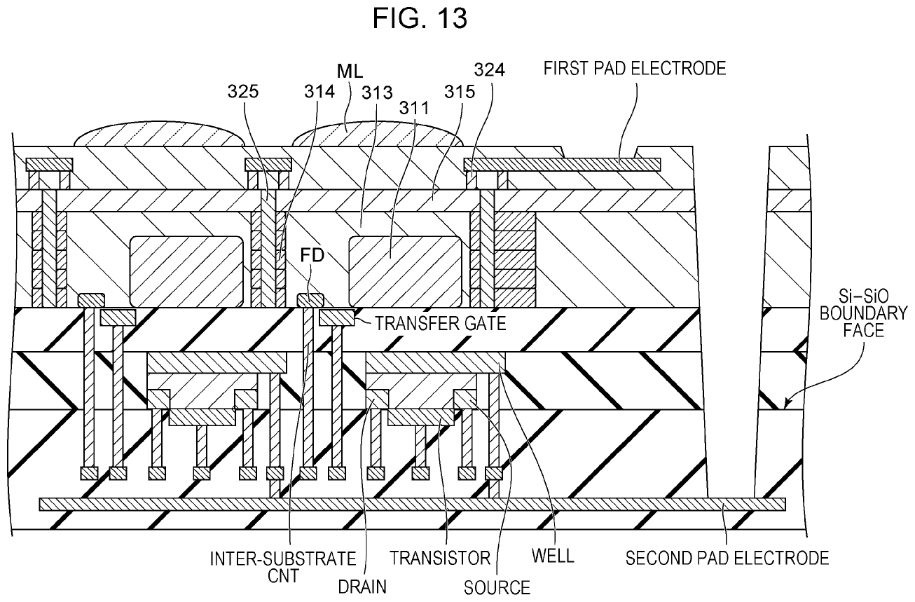

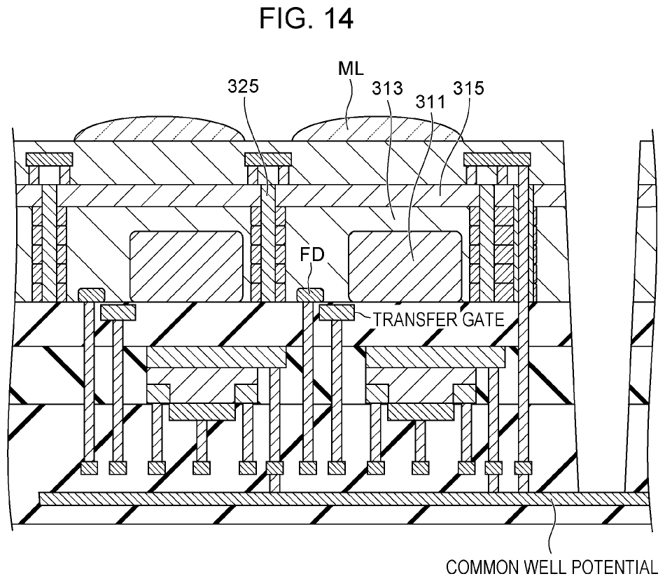

A photoelectric conversion apparatus according to the second embodiment is described below with reference to FIGS. 13 and 14. The photoelectric conversion apparatus according to the second embodiment includes a pixel including a CMOS image sensor and circuits formed in a plurality of semiconductor substrates. Differences from the first embodiment are mainly described below, and common descriptions are omitted.

FIG. 13 illustrates a cross-sectional view of two pixels of the photoelectric conversion apparatus according to the second embodiment. Like the first embodiment, a first substrate having a first surface (a light incident surface) and a second surface opposite the first surface includes a first semiconductor region 311, an FD, and a transfer gate. A second substrate stacked on the first substrate has a third surface facing the second surface and a fourth surface opposite the third surface, and the fourth surface has elements arranged thereon to read pixel signals. Examples of the element include a source follower transistor, a reset transistor, and a select transistor. The elements disposed in the second substrate are not limited thereto and may further include a signal processing circuit located downstream of the transistors.

The first substrate and the second substrate are connected by a contact electrode (an inter-substrate contact), and a signal for driving the gate of a transfer transistor and a signal for outputting the voltage of the FD are transmitted across the substrates.

The photoelectric conversion apparatus illustrated in FIG. 13 includes a first Pad electrode and a second Pad electrode. The first Pad electrode is provided adjacent to the light incident surface of the first substrate and is used to supply a voltage to a well of the first substrate via the contact electrode 324 provided adjacent to the light incident surface of the first substrate. The second Pad electrode is provided adjacent to the surface opposite the light incident surface of the second substrate and is used to supply a voltage to a well of the second substrate.

Different voltages may be supplied to the wells of the first substrate and the wells of the second substrate.

By making the supplied voltages independent, for example, it is possible to separate the influences of instability of power source on the two substrates.

FIG. 14 illustrates a modification of the photoelectric conversion apparatus according to the second embodiment.

In the configuration illustrated in FIG. 14, a Pad electrode is provided adjacent to the fourth surface of the second substrate. According to the configuration, the first Pad electrode and the second Pad electrode illustrated in FIG. 13 are formed as a common electrode.

A voltage supplied from the Pad electrode provided adjacent to the second substrate is supplied to the well of the first substrate via a through electrode or the like. Therefore, a signal for driving the gate of the transfer transistor, a signal for outputting the voltage of the FD, and the well potential are transmitted between the first substrate and the second substrate. The through electrode for transmitting the well potential between the first substrate and the second substrate is required to be formed in the peripheral portion of the pixel, for example, and each of the pixels need not have a conductive line. One through electrode may be provided for a plurality of pixels.

According to the configuration, the man-hours for the Pad opening process can be reduced as compared with that required for the configuration illustrated in FIG. 13. In addition, the well potential can be more easily shared by the first substrate and the second substrate.

### Third Embodiment

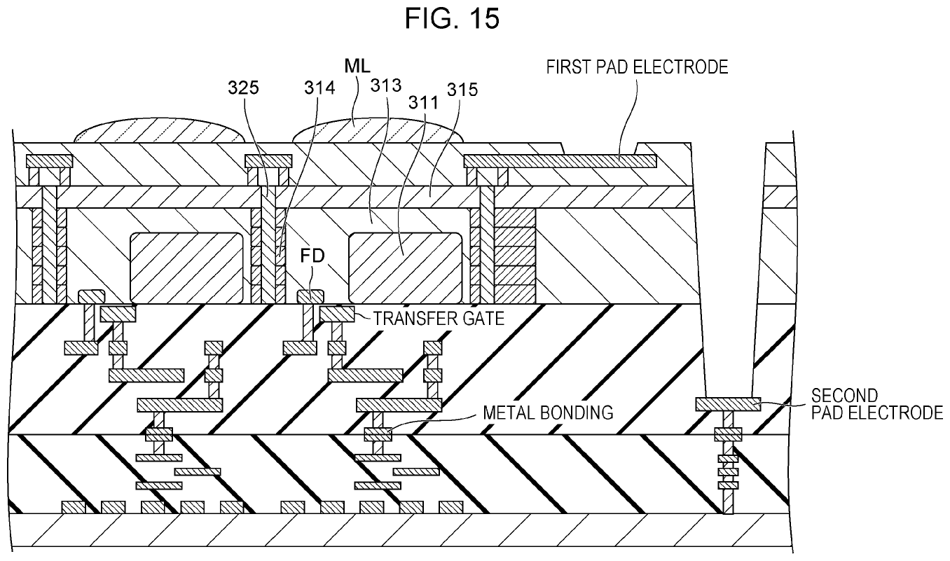

A photoelectric conversion apparatus according to the third embodiment is described below with reference to FIGS. 15 to 17. The photoelectric conversion apparatus according to the third embodiment includes a pixel including a CMOS image sensor and circuits formed in a plurality of semiconductor substrates, and the semiconductor substrates are stacked in a manner different from the second embodiment. Differences from the second embodiment are mainly described below, and common descriptions are omitted.

FIG. 15 is a cross-sectional view of two pixels of the photoelectric conversion apparatus according to the third embodiment. Like the second embodiment, a first semiconductor region 311, an FD, and a transfer gate are provided in the first substrate having a light incident surface. In a second substrate that is stacked on the first substrate, elements for reading pixel signals, such as a source follower transistor, a reset transistor, and a select transistor, are disposed. The elements disposed in the second substrate are not limited thereto and may further include a signal processing circuit following stage of the elements.

The first substrate and the second substrate are connected by bonding metal conductive lines. A first bonding portion included in a first wiring structure of the first substrate is bonded to a second bonding portion included in a second wiring structure of the second substrate at a bonding plane between the first wiring structure and the second wiring structure. In addition, a first insulating member included in the first wiring structure is bonded to a second insulating member included in the second wiring structure at the bonding plane between the first wiring structure and the second wiring structure. An example of the metal conductive line is a Cu-contained conductive line.

As in FIG. 13, in the photoelectric conversion apparatus illustrated in FIG. 15, a first Pad electrode is provided adjacent to the light incident surface of the first substrate, and a second Pad electrode is provided in the wiring layer adjacent to a surface opposite the light incident surface. The second Pad electrode may be provided in the first wiring layer closer to the first substrate than the bonding plane or may be provided in the second wiring layer closer to the second substrate than the bonding plane. By providing the Pad electrode for each of the well potentials of the substrates, it is possible to separate the influences of instability of power source on the substrates.

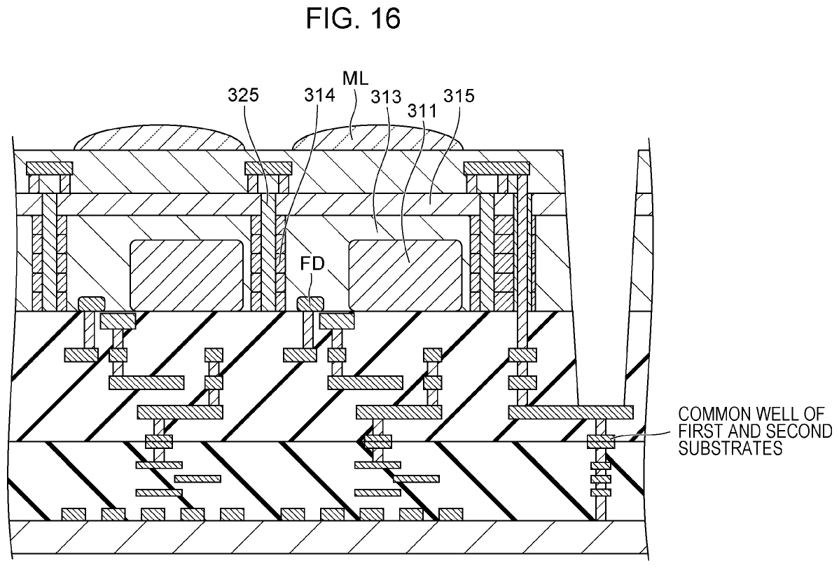

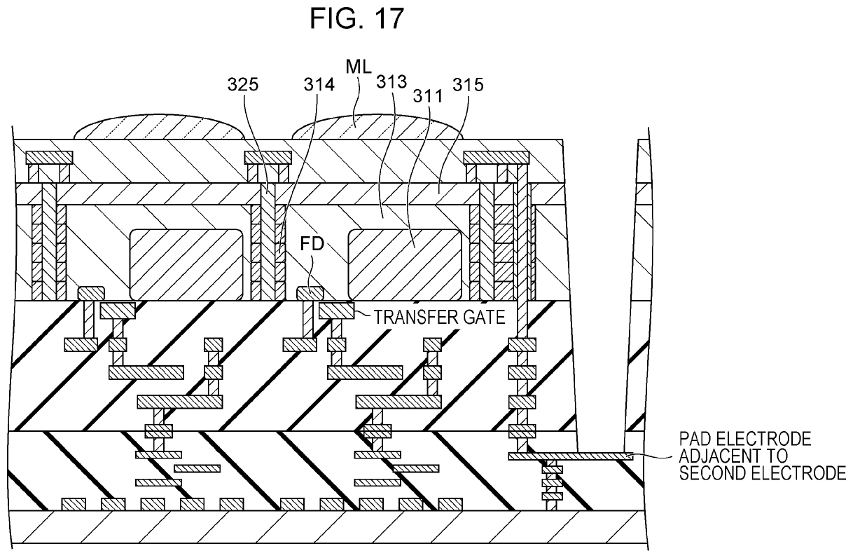

As illustrated in FIGS. 16 and 17, the Pad electrode for supplying voltage to the well of the first substrate and the Pad electrode for supplying voltage to the well of the second substrate may be integrated into a common electrode. In FIG. 16, the Pad electrode is provided in a conductive line closer to the first substrate than a bonding plane, and a voltage is supplied to the well of the first substrate via a through electrode. In FIG. 17, the Pad electrode is provided in a conductive line closer to the second substrate than the bonding plane. A voltage is supplied to the well of the first substrate via a through electrode or metal joining. In either case, the man-hours required for the Pad opening process can be decreased.

### Fourth Embodiment

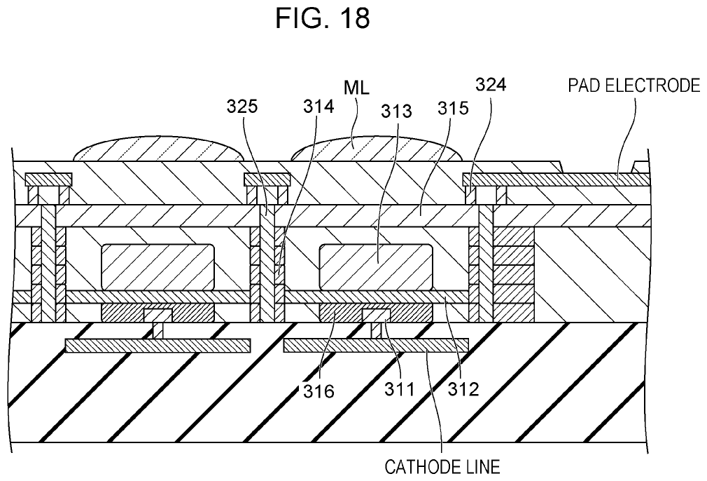

A photoelectric conversion apparatus according to the fourth embodiment is described below with reference to FIGS. 18 to 22. The fourth embodiment provides a photoelectric conversion apparatus in which pixels each including an APD and circuits are formed in the same semiconductor substrate. Differences from the first embodiment are mainly described below, and common descriptions are omitted.

FIG. 18 is a cross-sectional view of two pixels of a photoelectric conversion element 102 of the photoelectric conversion apparatus according to the fourth embodiment, taken in a direction perpendicular to the surface direction of a substrate. FIG. 18 corresponds to the cross section taken along line XVIII-XVIII of FIG. 7.

The structure and function of the photoelectric conversion element 102 are described below. The photoelectric conversion element 102 includes a first semiconductor region 311, a third semiconductor region 313, and a sixth semiconductor region 316 of N-type. The photoelectric conversion element 102 further includes a second semiconductor region 312, a fourth semiconductor region 314, and a fifth semiconductor region 315 of P-type.

According to the present embodiment, as illustrated in the cross section illustrated in FIG. 18, the N-type first semiconductor region 311 is formed in the vicinity of the second surface opposite the first surface, which is the light incident surface, of the semiconductor substrate (at a first depth), and the N-type sixth semiconductor region 316 is formed around the first semiconductor region 311. The P-type second semiconductor region 312 is formed at a position (at a second depth) so as to overlap the first semiconductor region 311 and the sixth semiconductor region 316 in plan view. The N-type third semiconductor region 313 is further disposed at a position (at a third depth) so as to overlap the second semiconductor region 312 in a plan view, and an N-type semiconductor region is formed around the third semiconductor region 313. Furthermore, the P-type fifth semiconductor region 315 is formed adjacent to the first surface.

The first semiconductor region 311 has a higher N-type impurity concentration than the third semiconductor region 313.

A PN junction is formed between the P-type second semiconductor region 312 and the N-type first semiconductor region 311. By making the impurity concentration of the second semiconductor region 312 lower than that of the first semiconductor region 311, the entire portion of the second semiconductor region 312 that overlaps the center of the first semiconductor region in plan view is turned into a depletion layer region. At this time, the potential difference between the first semiconductor region 311 and the second semiconductor region 312 is greater than the potential difference between the second semiconductor region 312 and the third semiconductor region 313. In addition, the depletion layer region extends to a part of the first semiconductor region 311, and a strong electric field is induced in the extended depletion layer region. The strong electric field causes avalanche multiplication in the depletion layer region extending to the part of the first semiconductor region 311, and an electric current based on the amplified charge is output as signal charge. When light incident on the photoelectric conversion element 102 is photoelectrically converted and avalanche multiplication occurs in the depletion layer region (an avalanche multiplication region), the generated charge of the first conductivity type is collected in the first semiconductor region 311.

Although in FIG. 18, the sixth semiconductor region 316 and the third semiconductor region 313 are formed to have approximately the same size, the size of each of the semiconductor regions is not limited thereto. For example, the third semiconductor region 313 may be formed larger than the sixth semiconductor region 316 to collect charge from a wider area into the first semiconductor region 311.

In addition, the sixth semiconductor region 316 may be a P-type semiconductor region instead of an N-type semiconductor region.

In this case, the P-type impurity concentration of the sixth semiconductor region 316 is set lower than the P-type impurity concentration of the second semiconductor region 312. This is because if the impurity concentration of the sixth semiconductor region 316 is too high, an avalanche multiplication region is formed between the sixth semiconductor region 316 and the first semiconductor region 311, increasing the dark count rate (DCR).

The pixels are separated by a pixel separation portion 325 having a trench structure, and the P-type fourth semiconductor region 314 formed around the pixel separates adjacent photoelectric conversion elements by a potential barrier. Since the photoelectric conversion elements are also separated by the potential of the fourth semiconductor region 314, a trench structure such as the pixel separation portion 325 is not essential as a pixel separation portion. When the pixel separation portion 325 having the trench structure is provided, the depth and position of the trench structure are not limited to those in the configuration illustrated in FIG. 18. The pixel separation portion 325 may be DTI (deep trench isolation) that penetrates the semiconductor layer or may be DTI that does not penetrate the semiconductor layer. A metal may be embedded in the DTI to improve the light shielding performance. The pixel separation portion 325 may be made of SiO, a fixed charge film, a metal member, Poly-Si, or any combination thereof. A configuration may be employed in which the pixel separation portions 325 surround the entire periphery of the photoelectric conversion element in plan view. Alternatively, a configuration may be employed in which, for example, the pixel separation portions 325 are disposed on the opposite sides of the photoelectric conversion element. The DCR may be reduced by applying a voltage to the embedded member to induce charge at the trench interface.

A pinning film and a planarization film (not illustrated) are further formed adjacent to the light incident surface of the semiconductor layer. Furthermore, a microlenses ML are formed adjacent to the light incident surface. Still furthermore, a filter layer (not illustrated) or the like may be disposed adjacent to the light incident surface. As the filter layer, an optical filter, such as a color filter, an infrared cut filter, or a monochrome filter, can be used. As the color filter, an RGB color filter, an RGBW color filter, or the like can be used.

A wiring structure including a conductor and an insulating film is provided on the surface opposite the light incident surface of the semiconductor layer. An interlayer film, which is the insulating film, is provided between a conductive line and the semiconductor layer and between wiring layers.

In the photoelectric conversion apparatus according to the present embodiment, an anode line is provided adjacent to the light incident surface of the semiconductor substrate, and a cathode line is provided adjacent to the surface opposite the light incident surface. The cathode line supplies a first voltage (a cathode voltage) to the first semiconductor region 311, and the anode line supplies a second voltage (an anode voltage) to the fourth semiconductor region 314 via the contact electrode 324.

When the anode line and the cathode line are provided in the same wiring layer, the wiring layout is limited in order to maintain the withstand voltage between the conductive lines. According to the present configuration, since the anode line and the cathode line are provided in different wiring layers with the substrate therebetween, the wiring layout is highly flexible, which is advantageous in reducing the pixel size, for example.

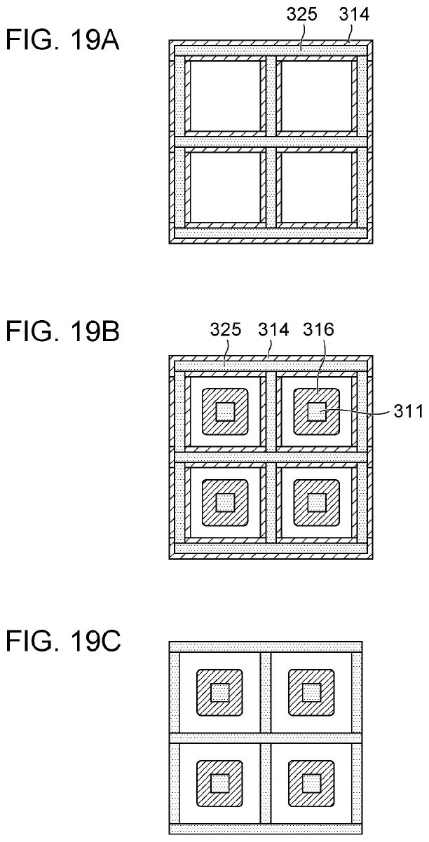

FIGS. 19A to 19C are plan views of four pixels of the photoelectric conversion apparatus according to the fourth embodiment.

FIG. 19A is a plan view illustrating the layout of the fourth semiconductor region 314 as viewed from the first surface, and FIG. 19B is a plan view as viewed from the second surface. FIG. 19C illustrates a modification of the layout illustrated in FIG. 19B.

As illustrated in FIGS. 19A and 19B, the fourth semiconductor region 314 is continuously formed from the front surface to the back surface of the semiconductor substrate for pixel separation. In addition, in existing configurations in which the anode potential is supplied from the second surface, the fourth semiconductor region is to be formed on the surface opposite the light incident surface at least in a region where the contact potential is formed.

In the case of an SPAD, a potential difference of nearly 30 V is formed between the first semiconductor region 311 to which the cathode voltage is supplied and the fourth semiconductor region 314 to which the anode voltage is supplied in order to cause avalanche multiplication to occur. For this reason, in one embodiment, the first semiconductor region 311 and the fourth semiconductor region 314 are located as far apart as possible. However, the pixel size can be reduced with decreasing distance between the first semiconductor region 311 and the fourth semiconductor region 314.

When the anode line is disposed on the first surface and the anode potential is supplied from the light incident surface side as in the photoelectric conversion apparatus according to the present embodiment, formation of the fourth semiconductor region 314 on the second surface is not needed. This configuration enables further reduction in the size of the pixel.

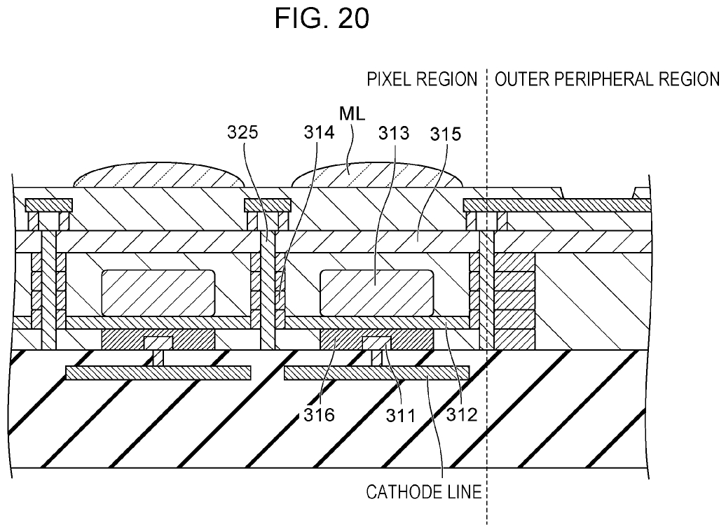

FIG. 20 is a cross-sectional view of the photoelectric conversion apparatus illustrated in FIG. 19C.

To reduce the size of the pixel, the fourth semiconductor region 314 is not provided in the vicinity of the second surface in the pixel region. The fourth semiconductor region 314 may be formed in the outer peripheral region.

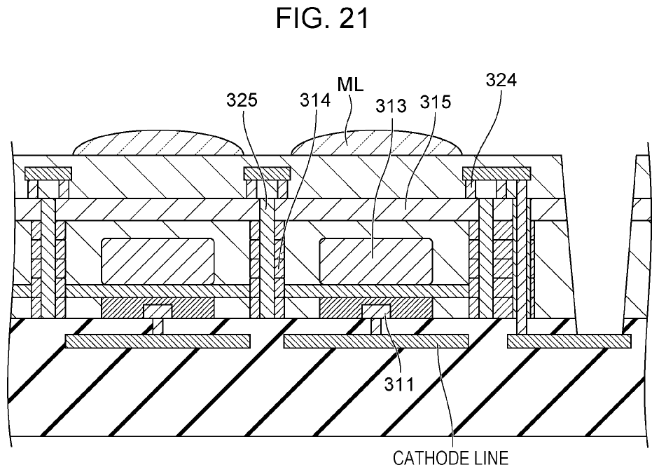

FIG. 21 illustrates an example of how to form the Pad electrode of the photoelectric conversion apparatus according to the fourth embodiment. FIG. 21 illustrates an example in which the Pad electrode is formed in the wiring structure adjacent to the second surface of the semiconductor substrate. A well potential is supplied to the contact electrode 324 adjacent to the first surface via the pixel separation portion 325 and the like.

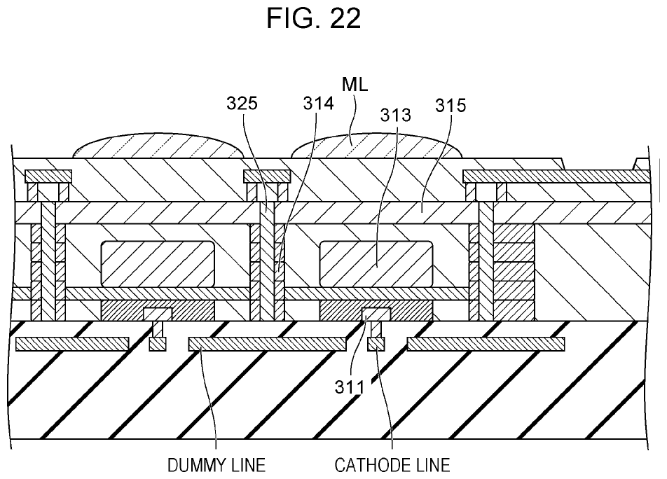

In FIG. 22, the cathode line and a dummy line are provided in the wiring structure adjacent to the second surface. The dummy line is a wire which is floating or a wire to which a fixed electric potential is applied. Examples of a fixed electric potential include the anode potential, the cathode potential, and an intermediate potential between the anode potential and the cathode potential. By providing such wiring, the light transmitted toward the second surface of the substrate is reflected to the inside of the pixel, resulting in improvement of the photoelectric conversion efficiency and prevention of a change in breakdown voltage over time.

For the purpose of light reflection, the same effect can be obtained by extending the cathode line. However, to speed up the SPAD operation, it is advantageous to keep the parasitic capacitance on the cathode electrode small. Therefore, in one embodiment, it is to make the size of the cathode electrode minimized. For this reason, it is effective to use, as a dummy line, a line other than the cathode line.

### Fifth Embodiment

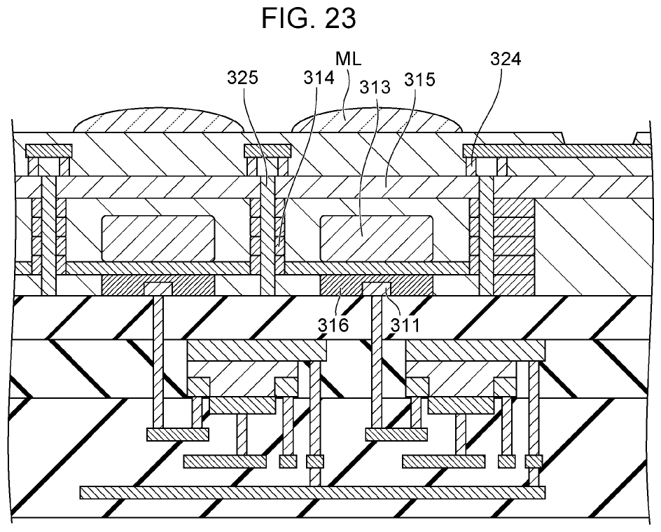

A photoelectric conversion apparatus according to the fifth embodiment is described below with reference to FIG. 23. According to the fifth embodiment, the photoelectric conversion apparatus includes a pixel including an APD and circuits formed in a plurality of semiconductor substrates. Differences from the fourth embodiment are mainly described below, and common descriptions are omitted.

FIG. 23 illustrates a cross-sectional view of two pixels of the photoelectric conversion apparatus according to the fifth embodiment. Like the fourth embodiment, a PAD is provided on the first substrate having the light incident surface. Elements, such as a quenching circuit, a waveform shaping circuit, and a signal processing circuit, are arranged in the second substrate stacked on the first substrate. The elements arranged in the second substrate are not limited thereto and may further include a signal processing circuit following stage of the circuits.

The first substrate and the second substrate are connected by contact electrodes 324.

### Sixth Embodiment

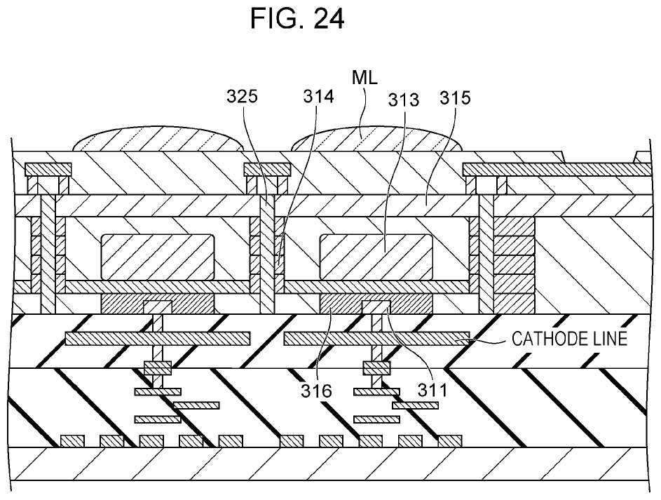

A photoelectric conversion apparatus according to the sixth embodiment is described below with reference to FIG. 24. The photoelectric conversion apparatus according to the sixth embodiment includes a pixel including an APD and circuits formed in a plurality of semiconductor substrates that are stacked by a method different from that of the fifth embodiment. Differences from the fourth embodiment are mainly described below, and common descriptions are omitted.

FIG. 24 illustrates a cross-sectional view of two pixels of the photoelectric conversion apparatus according to the fifth embodiment. Like the fourth embodiment, an APD is provided in the first substrate adjacent to the light incident surface. Elements, such as a quenching circuit, a waveform shaping circuit, and a signal processing circuit, are arranged in the second substrate stacked on the first substrate. The elements arranged in the second substrate are not limited thereto and may further include a signal processing circuit following stage of the circuits.

The first substrate and the second substrate are connected by bonding metal conductive lines. In a bonding plane between the first substrate and the second substrate, a metal conductive line exposed from the surface of the first substrate is bonded to a metal conductive line exposed from the surface of the second substrate. Similarly, in the bonding plane, an insulating member on the surface of the first substrate is bonded to an insulating member on the surface of the second substrate. An example of the metal conductive line is a Cu-contained conductive line.

### Seventh Embodiment

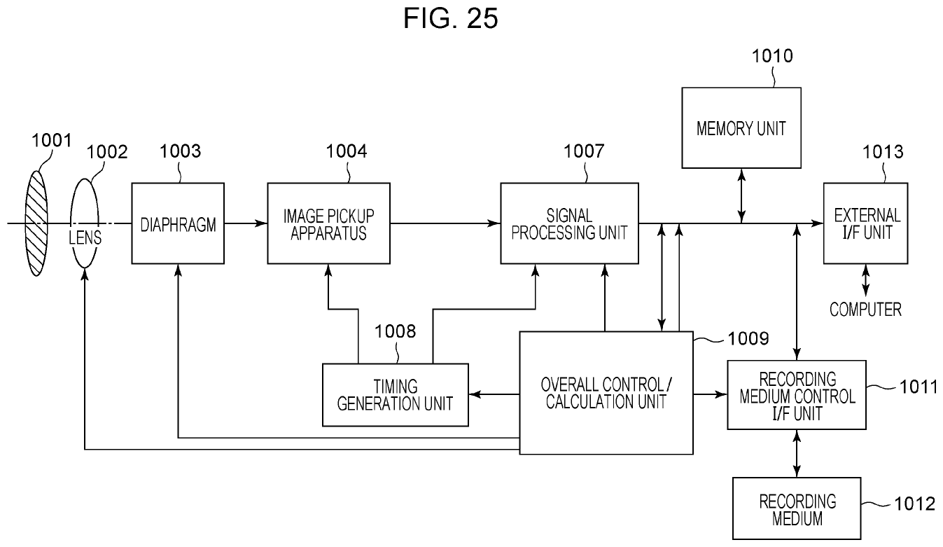

A photoelectric conversion system according to the present embodiment is described below with reference to FIG. 25. FIG. 25 is a block diagram illustrating a schematic configuration of the photoelectric conversion system according to the present embodiment.

The photoelectric conversion apparatuses described in each of the first to sixth embodiments can be applied to a variety of photoelectric conversion systems. Examples of an applicable photoelectric conversion system include a digital still camera, a digital camcorder, a surveillance camera, a copying machine, a facsimile, a mobile phone, on-vehicle camera, and an observation satellite. In addition, a camera module including an optical system, such as a lens, and an image pickup apparatus is included in the photoelectric conversion systems. FIG. 25 is a block diagram of a digital still camera as an example of the photoelectric conversion system.

The photoelectric conversion system illustrated in FIG. 25 includes an image pickup apparatus 1004 that is an example of a photoelectric conversion apparatus and a lens 1002 that forms an optical image of an object on the image pickup apparatus 1004. The photoelectric conversion system further includes a diaphragm 1003 for controlling the amount of light passing through the lens 1002 and a barrier 1001 for protecting the lens 1002. The lens 1002 and the diaphragm 1003 form an optical system for collecting light onto the image pickup apparatus 1004. The image pickup apparatus 1004 is the photoelectric conversion apparatus according to any one of the above-described embodiments. The image pickup apparatus 1004 converts an optical image formed by the lens 1002 into an electrical signal.

The photoelectric conversion system further includes a signal processing unit 1007 that serves as an image generation unit that generates an image by processing an output signal output from the image pickup apparatus 1004. The signal processing unit 1007 performs various corrections and compressions as necessary and outputs image data. The signal processing unit 1007 may be formed in a semiconductor substrate having the image pickup apparatus 1004 provided therein or may be formed in a semiconductor substrate other than the semiconductor substrate having the image pickup apparatus 1004 therein.

The photoelectric conversion system further includes a memory unit 1010 for temporarily storing image data and an external interface unit (external I/F unit) 1013 for communicating with an external computer or the like. Still furthermore, the photoelectric conversion system includes a recording medium 1012, such as a semiconductor memory, for recording and reading image data therein and therefrom, and a recording medium control interface unit (recording medium control I/F unit) 1011 for recording or reading data in and from the recording medium 1012. The recording medium 1012 may be built in the photoelectric conversion system or may be removable.

Furthermore, the photoelectric conversion system includes an overall control/calculation unit 1009 that performs control of various calculations and overall control of the digital still camera and a timing generation unit 1008 that outputs various timing signals to the image pickup apparatus 1004 and the signal processing unit 1007. The timing signal and the like may be input from the outside, and the photoelectric conversion system can include at least the image pickup apparatus 1004 and the signal processing unit 1007 that processes the output signal output from the image pickup apparatus 1004.

The image pickup apparatus 1004 outputs an image pickup signal to the signal processing unit 1007. The signal processing unit 1007 performs predetermined signal processing on the image pickup signal output from the image pickup apparatus 1004 and outputs image data. The signal processing unit 1007 generates an image using the image pickup signal.

As described above, according to the present embodiment, a photoelectric conversion system that employs the photoelectric conversion apparatus (the image pickup apparatus) of any one of the above-described embodiments can be achieved.

### Eighth Embodiment

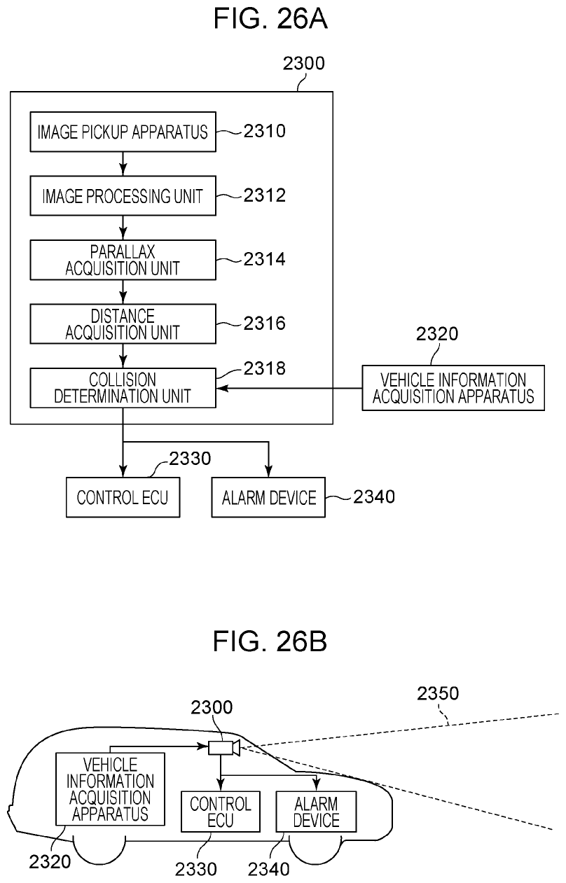

A photoelectric conversion system and a mobile object according to the present embodiment are described below with reference to FIGS. 26A and 26B. FIGS. 26A and 26B are diagrams illustrating the configurations of the photoelectric conversion system and the mobile object according to the present embodiment.

FIG. 26A illustrates an example of the photoelectric conversion system for an on-vehicle camera. A photoelectric conversion system 2300 includes an image pickup apparatus 2310. The image pickup apparatus 2310 is the photoelectric conversion apparatus described in any one of the above-described embodiments. The photoelectric conversion system 2300 includes an image processing unit 2312 that performs image processing on a plurality of image data acquired by the image pickup apparatus 2310 and a parallax acquisition unit 2314 that calculates a parallax (the phase difference of a parallax image) from the plurality of image data acquired by the photoelectric conversion system 2300. The photoelectric conversion system 2300 further includes a distance acquisition unit 2316 that calculates the distance to the object on the basis of the calculated parallax and a collision determination unit 2318 that determines the collision probability on the basis of the calculated distance. The parallax acquisition unit 2314 and the distance acquisition unit 2316 are examples of distance information acquisition units for acquiring information regarding the distance to a physical object. That is, the distance information is information related to a parallax, a defocus amount, the distance to a physical object, and the like. The collision determination unit 2318 may use any one of these pieces of distance information to determine the collision probability. The distance information acquisition unit may be implemented by dedicatedly designed hardware or may be implemented by a software module.

Alternatively, the distance information acquisition unit may be implemented by a field programmable gate array (FPGA), an application specific integrated circuit (ASIC), or combinations thereof.

The photoelectric conversion system 2300 is connected to a vehicle information acquisition apparatus 2320. Thus, the photoelectric conversion system 2300 can acquire vehicle information, such as a vehicle speed, a yaw rate, and a steering angle. In addition, the photoelectric conversion system 2300 is connected to a control ECU 2330 which is a control unit that outputs a control signal for generating a braking force to the vehicle on the basis of the determination result of the collision determination unit 2318. Furthermore, the photoelectric conversion system 2300 is connected to an alarm device 2340 that emits an alarm to a driver on the basis of the determination result of the collision determination unit 2318. For example, if the collision determination unit 2318 determines that the collision probability is high, the control ECU 2330 performs vehicle control to avoid collisions or reduce damage by braking, releasing the accelerator pedal, or reducing the engine output. The alarm device 2340 emits an alarm by, for example, sounding the alarm, displaying alarm information on a screen of a car navigation system, or vibrating a seat belt or steering wheel.

According to the present embodiment, the photoelectric conversion system 2300 captures the image of the surroundings of the vehicle, for example, the front view or rear view of the vehicle. FIG. 26B illustrates a photoelectric conversion system for capturing the image of the front view of the vehicle (an image capture range 2350). The vehicle information acquisition apparatus 2320 sends an instruction to the photoelectric conversion system 2300 or the image pickup apparatus 2310. Such a configuration can improve the accuracy of distance measurement.

While an example of performing control so as not to collide with another vehicle has been described, the configuration can also be applied to control of self-driving vehicles to follow another vehicle or control of self-driving vehicles to keep the lane. Furthermore, the photoelectric conversion system can be applied to autonomous driving control for, for example, following another vehicle and keeping the lane. Furthermore, the photoelectric conversion system can be applied not only to a vehicle, such as one's own vehicle, but also to a mobile object (a moving apparatus), such as a boat, an aircraft, or an industrial robot. Still furthermore, the photoelectric conversion system can be applied not only to a mobile object but also to equipment that uses object recognition over a wide area, such as an intelligent transportation system (ITS).

### Ninth Embodiment

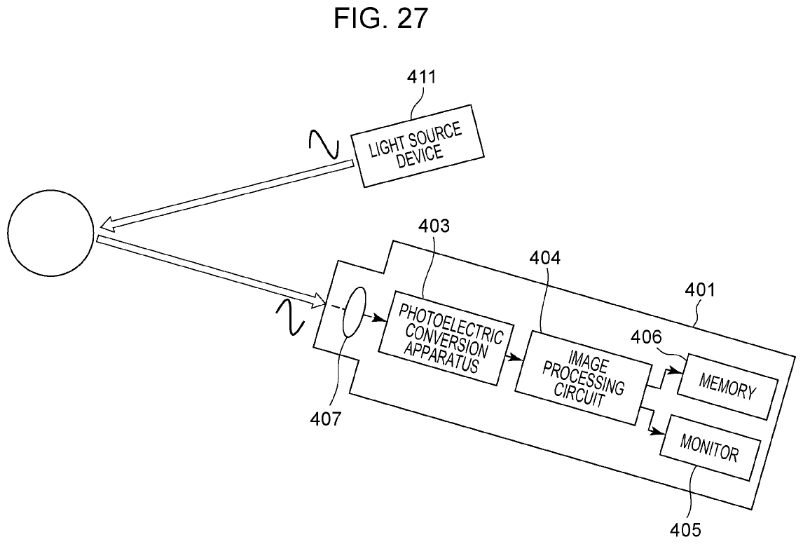

A photoelectric conversion system according to the present embodiment is described with reference to FIG. 27. FIG. 27 is a block diagram illustrating a configuration example of a range image sensor, which is the photoelectric conversion system of the present embodiment.

As illustrated in FIG. 27, a range image sensor 401 includes an optical system 407, a photoelectric conversion apparatus 403, an image processing circuit 404, a monitor 405, and a memory 406. The range image sensor 401 receives light (modulated light or pulsed light) projected from the light source device 411 toward an object and reflected by the surface of an object and, thus, can obtain a range image in accordance with the distance to the object.

The optical system 407 includes one or more lenses. The optical system 407 guides image light (incident light) from the object to the photoelectric conversion apparatus 403 and forms an image on the light receiving surface (a sensor unit) of the photoelectric conversion apparatus 403.

As the photoelectric conversion apparatus 403, the photoelectric conversion apparatus of any one of the embodiments described above is applied, and a distance signal indicating the distance obtained from the received light signal output from the photoelectric conversion apparatus 403 is supplied to the image processing circuit 404.

The image processing circuit 404 performs image processing to construct a range image based on the distance signal supplied from the photoelectric conversion apparatus 403. The range image (image data) obtained through the image processing is supplied to the monitor 405 and is displayed. In addition, the range image is supplied to the memory 406 and is stored (recorded).

In the range image sensor 401 configured in this way, by applying the above-described photoelectric conversion apparatus, it is possible to obtain, for example, a more accurate range image in accordance with improvement of the characteristics of the pixels.

### Tenth Embodiment

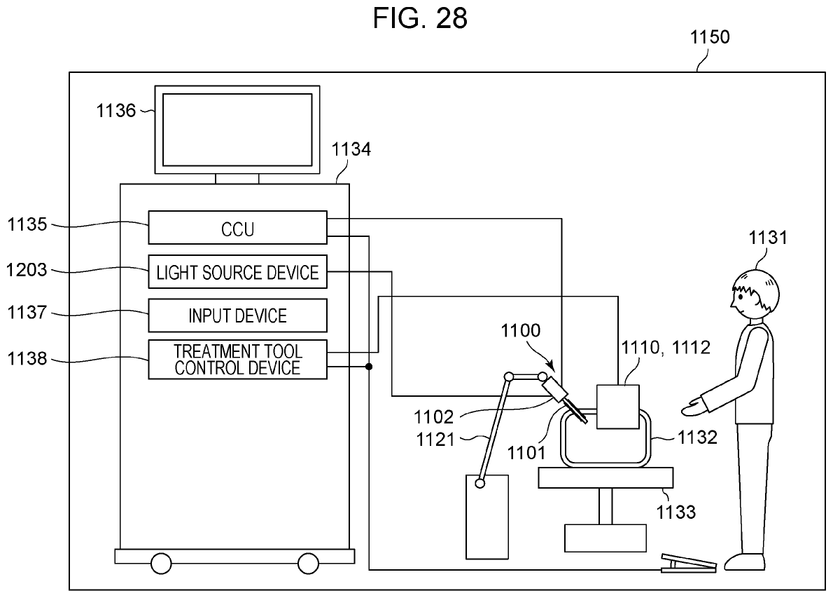

The photoelectric conversion system according to the present embodiment is described below with reference to FIG. 28. FIG. 28 illustrates an example of a schematic configuration of an endoscopic surgery system, which is the photoelectric conversion system according to the present embodiment.

FIG. 28 illustrates how an operator (a medical doctor) 1131 uses an endoscopic surgery system 1150 to perform surgery on a patient 1132 on a patient bed 1133. As illustrated in FIG. 28, the endoscopic surgery system 1150 includes an endoscope 1100, a surgical tool 1110, and a cart 1134 having a variety of devices for endoscopic surgery mounted therein.

The endoscope 1100 is composed of a lens barrel 1101, a predetermined length of the front end of which is to be inserted into the body cavity of the patient 1132, and a camera head 1102, which is connected to the base end of the lens barrel 1101. In FIG. 28, the endoscope 1100 is illustrated that is configured as a so-called rigid scope having the lens barrel 1101 that is rigid. However, the endoscope 1100 may be configured as a so-called flexible scope having a lens barrel that is flexible.

An opening having an objective lens fitted thereinto is provided at the front end of the lens barrel 1101. A light source device 1203 is connected to the endoscope 1100, and light generated by the light source device 1203 is guided to the front end of the lens barrel 1101 by a light guide extending inside the lens barrel 1101. The light is emitted to an observation object in the body cavity of the patient 1132 through the objective lens. The endoscope 1100 may be a straight-viewing endoscope, an oblique-viewing endoscope, or a side-viewing endoscope.

An optical system and a photoelectric conversion apparatus are provided inside the camera head 1102, and the reflected light (observation light) from the observation object is focused on the photoelectric conversion apparatus by the optical system. The photoelectric conversion apparatus photoelectrically converts the observation light to generate an electrical signal corresponding to the observation light. That is, an image signal corresponding to the observation image is generated. As the photoelectric conversion apparatus, the photoelectric conversion apparatus described in any one of the above embodiments can be used. The image signal is transmitted to a camera control unit (CCU) 1135 in the form of RAW data.

The CCU 1135 includes a central processing unit (CPU), a graphics processing unit (GPU), and the like. The CCU 1135 comprehensively controls the operations performed by the endoscope 1100 and a display device 1136. Furthermore, the CCU 1135 receives an image signal from the camera head 1102 and performs various image processing, such as development processing (demosaicing), for displaying an image based on the image signal.

Under the control of the CCU 1135, the display device 1136 displays an image based on the image signal subjected to image processing performed by the CCU 1135.

The light source device 1203 includes a light source, such as a light emitting diode (LED), and supplies the endoscope 1100 with irradiation light for capturing the image of a surgical site or the like.

An input device 1137 is an input interface to the endoscopic surgery system 1150. A user can input a variety of information and instructions to the endoscopic surgery system 1150 via the input device 1137.

A treatment tool control device 1138 controls driving of an energy treatment tool 1112 for tissue cauterization, incision, blood vessel sealing, or the like.

The light source device 1203 that supplies irradiation light to the endoscope 1100 when the image of a surgical site is captured can include, for example, a white light source, such as an LED, a laser light source, or combinations thereof. When the white light source is configured by a combination of R, G, and B laser light sources, the output intensity and output timing of each of the colors (each of the wavelengths) can be controlled with high accuracy. Thus, white balance of a captured image can be adjusted in the light source device 1203. In this case, the observation target is irradiated with laser light from each of the R, G, and B laser light sources in a time-division manner, and driving of an image pickup element of the camera head 1102 is controlled in synchronization with the irradiation timing. In this way, an image corresponding to each of the RGB colors can be captured in a time-division manner. According to the technique, a color image can be obtained without providing a color filter on the image pickup element.

In addition, the driving of the light source device 1203 may be controlled such that the intensity of the output light is changed at predetermined time intervals. A high dynamic range without so-called crushed shadows and blown out highlights can be generated by controlling the driving of the image pickup elements of the camera head 1102 in synchronization with the timing of the change in the intensity of the light, acquiring images in a time-division manner, and combining the images.

In addition, the light source device 1203 may be configured so as to be able to supply light in a predetermined wavelength band range corresponding to special light observation. In special light observation, the wavelength dependency of light absorption by a body tissue is used, for example. More specifically, a high contrast image of a predetermined tissue, such as a blood vessel on the surface of the mucous membrane, is captured by irradiating the tissue with light in a narrower band than the irradiation light used during normal observation (that is, white light).

Alternatively, in special light observation, fluorescence observation may be performed in which an image is captured using fluorescence generated by irradiation with excitation light. In fluorescence observation, a body tissue is irradiated with excitation light, and fluorescence from the body tissue can be observed. Alternatively, a reagent, such as indocyanine green (ICG), is locally injected into the body tissue, and the body tissue is irradiated with excitation light corresponding to the fluorescence wavelength of the reagent. Thus, a fluorescent image can be obtained. The light source device 1203 can be configured so as to supply narrowband light and/or excitation light corresponding to the special light observation.

### Eleventh Embodiment

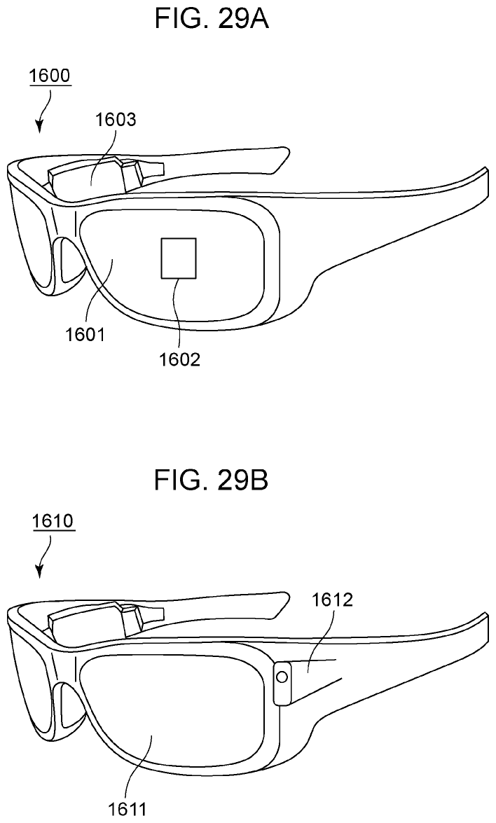

A photoelectric conversion system according to the present embodiment is described below with reference to FIGS. 29A and 29B. FIG. 29A illustrates glasses 1600 (smart glasses), which are the photoelectric conversion system according to the present embodiment. The glasses 1600 include a photoelectric conversion apparatus 1602. The photoelectric conversion apparatus 1602 is the photoelectric conversion apparatus described in any one of the above embodiments. A display device including a light emitting device, such as an OLED or an LED, may be provided on the rear surface side of a lens 1601. One or more photoelectric conversion apparatuses 1602 may be provided. Furthermore, a plurality of types of photoelectric conversion apparatuses may be combined and used. The mounting location of the photoelectric conversion apparatus 1602 is not limited to that illustrated in FIG. 29A.

The glasses 1600 further include a control device 1603. The control device 1603 functions as a power source that supplies electric power to the photoelectric conversion apparatus 1602 and the display device. In addition, the control device 1603 controls the operations performed by the photoelectric conversion apparatus 1602 and the display device. The lens 1601 has an optical system formed therein to focus light onto the photoelectric conversion apparatus 1602.

FIG. 29B illustrates glasses 1610 (smart glasses) according to an application example. The glasses 1610 include a control device 1612. The control device 1612 includes a photoelectric conversion apparatus corresponding to the photoelectric conversion apparatus 1602 and a display device. A lens 1611 includes, formed therein, the photoelectric conversion apparatus in the control device 1612 and an optical system for projecting light emitted from the display device. An image is projected to the lens 1611. The control device 1612 functions as a power source that supplies electric power to the photoelectric conversion apparatus and the display device and controls the operations performed by the photoelectric conversion apparatus and the display device. The control device may include a line-of-sight detection unit that detects the line of sight of a wearer. Infrared light may be used for line-of-sight detection. An infrared light emitting unit emits infrared light to the eyeballs of a user who is gazing at the display image. An image pickup unit including a light receiving element detects reflected light of the emitted infrared light from the eyeball and, thus, a captured image of the eyeball can be obtained. To reduce deterioration in image quality, a reduction unit is provided to reduce light from the infrared light emitting unit to a display unit in plan view.

The user's line of sight to the displayed image is detected from the captured infrared light images of the eyeball. Any known technique can be applied to line-of-sight detection using captured images of eyeballs. As an example, an eye gaze detection technique based on a Purkinje image obtained using reflection of irradiation light on the cornea.

More specifically, line-of-sight detection processing is performed on the basis of the pupillary-corneal reflection technique. The user's line of sight is detected by calculating a line of sight vector representing the orientation (the rotational angle) of the eyeball on the basis of the pupil image and the Purkinje image included in the captured eyeball image by using the pupillary-corneal reflection technique.

The display device according to the present embodiment may include a photoelectric conversion apparatus including a light receiving element and may control the display image of the display device on the basis of the user's line-of-sight information obtained from the photoelectric conversion apparatus.

More specifically, the display device determines a first field of view region that the user gazes at and a second field of view region other than the first field of view region on the basis of the line-of-sight information. The first field of view region and the second field of view region may be determined by a control unit of the display device. Alternatively, a first field of view region and a second field of view region determined by an external control device may be received. In the display area of the display device, the display resolution of the first field of view region may be controlled to be higher than the display resolution of the second field of view region. That is, the resolution of the second field of view region may be set to lower than that of the first field of view region.

Furthermore, the display area may have a first display area and a second display area different from the first display area, and a higher priority one of the first display area and the second display area may be determined on the basis of the line of sight information. The first field of view region and the second field of view region may be determined by the control unit of the display device or an external control device. Alternatively, a first field of view region and a second field of view region determined by an external control device may be received. The resolution of a high priority area may be set higher than the resolution of an area other than the high priority area. That is, the resolution of a relatively low priority area may be decreased.

Artificial intelligence (AI) may be used to determine the first field of view region and a high priority area. AI model may be a model configured to estimate the angle of the line of sight and the distance to an object in the line of sight from the eyeball image by using, as training data, eyeball images and the directions in which the eyeballs in the images are actually looking. The AI program may be stored in the display device, the photoelectric conversion apparatus, or an external device. When stored in the external device, the AI program is transmitted to the display device via communication.

In the case of display control based on visual recognition detection, the display control can be applied to smart glasses that further include a photoelectric conversion apparatus that captures the image of the outside. The smart glasses can display captured external information in real time.

### Modified Embodiments

The disclosure is not limited to the above embodiments, and various modifications can be made.

For example, an example in which part of the configuration of any one of the embodiments is added to another embodiment and an example in which part of the configuration of any one of the embodiments is replaced by part of another embodiment are also included in embodiments of the disclosure.

In addition, the photoelectric conversion systems according to the seventh embodiment and the eighth embodiment are examples of photoelectric conversion systems to which the photoelectric conversion apparatus can be applied, and a photoelectric conversion system to which the photoelectric conversion apparatus according to the disclosure can be applied is not limited to the configurations illustrated in FIG. 25 and FIGS. 26A and 26B. The same applies to the ToF system according to the ninth embodiment, the endoscope according to the tenth embodiment, and the smart glasses according to the eleventh embodiment.

It should be noted that the above-described embodiments merely illustrate specific examples for carrying out the disclosure, and the technical scope of the disclosure should not be construed to be limited by the embodiments. That is, the disclosure can be carried out in various forms without departing from its technical concept or main features.

According to the disclosure, it is possible to increase the flexibility of placement of the transistors.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-091510 filed Jun. 6, 2022, which is hereby incorporated by reference herein in its entirety.

What is claimed is:

1. An apparatus comprising:
a photodiode disposed in a first substrate having a first surface and a second surface opposite the first surface,
wherein the photodiode includes
a first region of a first conductivity type disposed at a first depth,
a second region of a second conductivity type disposed at a second depth that is deeper than the first depth with respect to the second surface,
a third region disposed at a third depth that is deeper than the second depth with respect to the second surface,
a fourth region in contact with the third region,
a first conductive line connected to the first region and disposed adjacent to the second surface,
a second conductive line connected to the fourth region and disposed adjacent to the first surface, and
a fourth conductive line formed in a wiring structure stacked adjacent to the second surface of the first substrate,
wherein the photodiode is configured such that a difference between a voltage applied to the first conductive line and a voltage applied to the second conductive line is greater than or equal to a breakdown voltage, and
wherein the second conductive line receives a potential supplied from an outside via the fourth conductive line.

2. The apparatus according to claim 1, wherein the fourth region is not disposed on the second surface.

3. The apparatus according to claim 1, further comprising:
a third conductive line formed in the wiring structure stacked adjacent to the second surface of the first substrate,
wherein the third conductive line is not connected to the first substrate.

4. The apparatus according to claim 1, wherein the photodiode includes a fifth region provided in contact with an end portion of the fourth region.

5. The apparatus according to claim 4, wherein the second conductive line supplies a potential to the third region via the fifth region.

6. The apparatus according to claim 1, comprising:
the second substrate stacked adjacent to the second surface of the first substrate,
wherein the second substrate has a third surface facing the second surface and a fourth surface opposite the third surface,
wherein the fourth surface has a transistor that is a part of a pixel circuit that processes a signal output from the photodiode, and
wherein the third surface has a fifth region to which a voltage is supplied.

7. The apparatus according to claim 1, comprising:
the first substrate;
the second substrate;
a first wiring structure stacked adjacent to the second surface of the first substrate; and
a second wiring structure disposed between the first wiring structure and the second substrate,
wherein a first bonding portion included in the first wiring structure is bonded to a second bonding portion included in the second wiring structure at a bonding plane between the first wiring structure and the second wiring structure, and
wherein a first insulating member included in the first wiring structure is bonded to a second insulating member included in the second wiring structure at the bonding plane between the first wiring structure and the second wiring structure.

8. An apparatus comprising:
a photodiode disposed in a first substrate having a first surface and a second surface opposite the first surface,
wherein the photodiode includes
a first region of a first conductivity type disposed at a first depth,
a second region of a second conductivity type disposed at a second depth that is deeper than the first depth with respect to the second surface,
a third region disposed at a third depth that is deeper than the second depth with respect to the second surface,
a fourth region in contact with the third region,
a first conductive line connected to the first region and disposed adjacent to the second surface,
a second conductive line connected to the fourth region and disposed adjacent to the first surface, and
a fifth conductive line formed in a wiring structure stacked adjacent to the first surface of the first substrate,
wherein a difference between a voltage applied to the first conductive line and a voltage applied to the second conductive line is greater than or equal to a breakdown voltage, and
wherein the second conductive line receives a potential supplied from an outside via the fifth conductive line.

9. The apparatus according to claim 8, wherein the fourth region is not disposed on the second surface.

10. The apparatus according to claim 8, further comprising:
a third conductive line formed in the wiring structure stacked adjacent to the second surface of the first substrate,
wherein the third conductive line is not connected to the first substrate.

11. The apparatus according to claim 8, wherein the photodiode includes a fifth region provided in contact with an end portion of the fourth region.

12. The apparatus according to claim 11, wherein the second conductive line supplies a potential to the third region via the fifth region.

13. The apparatus according to claim 8, wherein the second conductive line and the fifth conductive line are connected to each other by an electrode that penetrates the first substrate.

14. The apparatus according to claim 8, comprising:
the first substrate;
the second substrate;
a first wiring structure stacked adjacent to the second surface of the first substrate; and
a second wiring structure disposed between the first wiring structure and the second substrate,
wherein a first bonding portion included in the first wiring structure is bonded to a second bonding portion included in the second wiring structure at a bonding plane between the first wiring structure and the second wiring structure, and
wherein a first insulating member included in the first wiring structure is bonded to a second insulating member included in the second wiring structure at the bonding plane between the first wiring structure and the second wiring structure.

15. An apparatus comprising:
a first substrate having a first surface on which light is incident and the second surface opposite the first surface; and
a second substrate stacked adjacent to the second surface of the first substrate,
wherein the first substrate includes
an element including a first region of a first conductivity type and
a second region of a second conductivity type,
a third region in contact with the second region,
a first conductive line connected to the first region and used to read out a signal from the first region, and
a second conductive line provided adjacent to the first surface and used to supply a potential to the first substrate,
wherein the first substrate includes
a third surface facing the second surface, a fourth surface opposite the third surface, and
a transistor formed on the fourth surface, and
wherein the transistor is a part of a pixel circuit that processes a signal output from the element.

16. The apparatus according to claim 15, comprising:
a fifth conductive line formed in a wiring structure stacked adjacent to the first surface of the first substrate, and
wherein the second conductive line receives a potential supplied from an outside via the fifth conductive line.

17. The apparatus according to claim 16, wherein the second conductive line and the fifth conductive line are connected to each other by an electrode that penetrates the first substrate.

18. The apparatus according to claim 15, comprising:
the first substrate;
the second substrate;
a first wiring structure stacked adjacent to the second surface of the first substrate; and
a second wiring structure disposed between the first wiring structure and the second substrate,
wherein a first bonding portion included in the first wiring structure is bonded to a second bonding portion included in the second wiring structure at a bonding plane between the first wiring structure and the second wiring structure, and
wherein a first insulating member included in the first wiring structure is bonded to a second insulating member included in the second wiring structure at the bonding plane between the first wiring structure and the second wiring structure.

19. A system comprising:
the apparatus according claim 1; and
a processing unit configured to generate an image using a signal output from the apparatus.

20. A mobile object comprising:
the apparatus according to claim 1; and
a control unit configured to control movement of the mobile object using a signal output from the apparatus.
